(19) United States
(12) Patent Application Publication
(10) Pub. No.: US 2006/0255357 A1
(43) Pub. Date: Nov. 16, 2006

(54) Light emitting element mounting frame and light emitting device

(75) Inventors: Toshio Hata, Mihara-shi (JP); Takaaki Utsumi, Mihara-shi (JP); Daikaku Kimura, Mihara-shi (JP)

Correspondence Address: MORRISON & FOERSTER LLP, 755 PAGE MILL RD, PALO ALTO, CA, 94304-1018, US

(73) Assignee: SHARP KABUSHIKI KAISHA, Osaka-shi (JP)

(21) Appl. No.: 11/431,267

(22) Filed: May 9, 2006

(30) Foreign Application Priority Data
May 11, 2005 (JP) JP2005-138711
Feb. 15, 2006 (JP) JP2006-037952

(51) Int. Cl. H01L 33/00; H01L 29/22

(52) U.S. Cl. 257/99

(57) ABSTRACT

In the light emitting device of the present invention, a silver alloy layer is formed on at least a portion of the surface of a frame on which a light emitting element is mounted. Because of this structure, a light emitting element mounting frame and a light emitting device that have improved corrosion resistance and the like and superior efficiency in taking light emitted from light emitting element to the outside can be provided.

This nonprovisional application is based on Japanese Patent Applications Nos. 2005-138711 and 2006-037952 filed with the Japan Patent Office on May 11, 2005 and Feb. 15, 2006, respectively, the entire contents of which are hereby incorporated by reference.

### BACKGROUND OF THE INVENTION

1. Field of the Invention

The present invention relates to a light emitting element mounting frame and to a light emitting device. More specifically, the present invention relates to a light emitting element mounting frame and a light emitting device that have high reliability and high efficiency of taking light to the outside.

2. Description of the Background Art

FIG. 12 shows a structure of a light emitting device having a light emitting element mounted on a surface-mounting type frame. Referring to FIG. 12, a light emitting device 102 includes package electrodes 101 having an electrical contact with the outside, and package electrodes 101 are plated with noble metal such as silver or gold. On one package electrode 101, a light emitting element 103 is adhered by using Ag paste (see Japanese Patent Laying-Open No. 09-298314). As an example of a light emitting device using a lead frame, which is a light emitting element mounting frame of a different type from the above-described surface-mounting type, a light emitting device having a cup provided at a tip end of a silver-plated copper lead frame, on which an LED chip is die-bonded, has been known (see Japanese Patent Laying-Open No. 10-247750). Further, use of sputtering as a method of forming an Ag alloy film is disclosed in Japanese Patent Laying-Open No. 2005-029849.

In the light emitting device using the surface-mounting type frame or the lead frame described above, however, there is still room for improving efficiency of taking light emitted from the light emitting element to the outside. Further improvement in reliability, such as erosion resistance, has also been desired. As for the formation of the Ag alloy film by sputtering, considering that LED mounting frames and light emitting devices must be mass-produced, sputtering is not suitable for mass production and when the Ag alloy film is to be made thick, necessary time would be too long.

### SUMMARY OF THE INVENTION

In order to solve the above-described problems, an object of the present invention is to provide a light emitting element mounting frame and a light emitting device that have superior efficiency of taking light emitted from the light emitting element to the outside and have improved erosion resistance and the like.

The present invention provides a light emitting element mounting frame having a silver (Ag) alloy layer formed on at least a portion of the frame surface. By this structure, it becomes possible to permanently maintain high efficiency of taking light from the light emitting element mounting frame. The frame mounting the light emitting element may be almost fully covered by the silver alloy layer.

Further, the Ag alloy layer mentioned above may be any of Ag—Nd alloy, Ag—Nd—Cu alloy, Ag—Pd alloy, Ag—Pd—Cu alloy, Ag—Bi alloy and Ag—Nd—Au alloy. By this structure, erosion resistance, heat resistance and aggregation resistance can be improved.

The Ag alloy layer may be formed by plating or resistance heating, and a layer formed by plating is particularly preferable. When the Ag alloy layer is formed by plating, the time necessary for forming the Ag alloy layer can be reduced as compared with forming the layer by sputtering. Therefore, application of plating is preferable in manufacturing the LED mounting frames and the light emitting devices that must be mass-produced.

The frame described above may be a lead frame including a cup portion positioned to surround the light emitting element, and the Ag alloy layer may be formed on at least a portion of the lead frame. By this structure, a highly reliable lead frame can be realized, as the surface of the lead frame would not be deteriorated even if it were exposed to an atmosphere containing corrosive gas or the like.

The Ag alloy layer may be formed on the inner side of the cup portion facing the light emitting element. Because of such an arrangement, decrease in reflectance inside the cup portion of the lead frame can be avoided, and hence, efficiency of taking light to the outside can be improved.

Alternatively, the Ag alloy layer may be formed on a side surface of the cup portion. Thus, in the lead frame, light emitted from the light emitting element to the side surface can efficiently be reflected upward.

Alternatively, the Ag alloy layer may be formed at the bottom of the cup portion. Thus, adhesion strength of the light emitting element to the lead frame can be increased.

Alternatively, the Ag alloy layer may be formed at a portion where the lead frame is in contact with resin. Even when moisture or the like contained in the resin comes to be in contact with the Ag alloy layer, Ag alloy layer is not deteriorated, and therefore, a lead frame superior in electrical and optical characteristics can be provided.

Further, the Ag alloy layer may be formed at a region to be wire-bonded of the lead frame. This further improves adhesion between the lead frame and the light emitting element, and hence improves reliability of the light emitting device.

Further, the frame may be a surface-mounting type frame including a portion on which the light emitting element is mounted, an electrode terminal, and a cup portion positioned to surround the light emitting element, and the Ag alloy layer may be formed at any of the portion on which the light emitting element is mounted, the electrode terminal and the cup portion positioned to surround the light emitting element. As at least one of the portion on which the light emitting element is mounted, the electrode terminal and the cup portion positioned to surround the light emitting element has its surface formed of the Ag alloy layer, even when it comes to be in contact with moisture or the like in epoxy resin or the like, deterioration can be avoided at that portion, and therefore, one or both of good efficiency of taking light to the outside (optical characteristic) and good electrical characteristic can be ensured.

The Ag alloy layer may be formed on the inner side of the cup portion facing the light emitting element of the surface-mounting type frame. This prevents deterioration in the cup portion, and the light emitting device having good electrical and optical characteristics can be provided.

Alternatively, the Ag alloy layer may be formed at a portion of the cup portion where the resin comes to be in contact, of the surface-mounting type frame. Because of this structure, even when moisture or the like of the resin is brought into contact with the Ag alloy layer, deterioration does not occur, and a good frame for the light emitting element can be provided.

Alternatively, the Ag alloy layer may be formed at portion of the cup portion where a phosphor comes to be in contact, of the surface-mounting type frame. Because of this structure, even when a component of the phosphor contacts, the portion in contact is formed of Ag alloy layer, and a good frame for the light emitting element can be provided.

Further, the Ag alloy layer may be formed at a region to be wire-bonded to the electrode terminal of the surface-mounting type frame. Because of this structure, deterioration of the region to be wire-bonded of the electrode terminal can be avoided, and hence, a good frame for the light emitting device can be provided.

The present invention provides a light emitting device using any of the light emitting element mounting frames described above, wherein a conductive adhesive used for fixing the light emitting element on the frame contains Ag as a main component, and additionally contains at least Nd. Though Ag paste is known to become black, aggregation of Ag paste can be avoided, and adhesion between the light emitting element and the frame can be improved.

The present invention provides a light emitting device using any of the light emitting element mounting frame described above, wherein a conductive adhesive used for fixing the light emitting element may be Ag paste having an Ag alloy layer formed on its surface. This structure prevents deterioration of the Ag paste.

In the light emitting device using any of the light emitting element mounting frames described above, the light emitting element may have at least one wire per one surface. Therefore, even in a structure having two wires, such as in the case of a nitride type light emitting element in which light is emitted also to the substrate side, the Ag alloy layer covers the cup portion in the lead frame type, and covers the inner portion of the surface-mounting type frame, so that deterioration inside the cup portion can be avoided.

Further, the light emitting element may be a light emitting diode of infra-red to ultra-violet. The Ag alloy layer has high reflectance to the light from the light emitting diode in the range of infra-red to ultra-violet, and therefore, efficiency of taking light to the outside can be improved.

The light emitting element may be any of three chips of red, green and blue LEDs, one chip of blue LED, and one chip of ultra-violet LED. The Ag alloy layer exhibits high reflectance to the LEDs mentioned above, and therefore, it is desired that at least one chip of infra-red, red, green, blue, and ultra-violet is mounted as the light emitting element.

In the present invention, the Ag alloy layer is formed on a surface of at least one of a surface mounting type frame and a lead frame having a cup portion of a cup-shape on which the light emitting element is mounted. Therefore, efficiency of taking light from the light emitting layer to the outside is improved, and optical output of the light emitting device increases. Further, as the adhesion with the chip is improved, a highly reliable light emitting device can be realized. Further, as the Ag alloy layer is formed on a part of the surface-mounting type frame and on the lead frame having a cup portion of a cup-shape, deterioration of the frame can be avoided, and permanently reliable light emitting device can be realized.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a schematic cross-section of a light emitting device in accordance with Embodiment 1 of the present invention.

FIG. 2 is a schematic cross-section of a light emitting device in accordance with Embodiment 2 of the present invention.

FIG. 3 is a schematic cross-section of a light emitting device in accordance with Embodiment 3 of the present invention.

FIG. 4 is a schematic cross-section of a light emitting device in accordance with Embodiment 4 of the present invention.

FIG. 5 is a schematic cross-section of a light emitting device in accordance with Embodiment 5 of the present invention.

FIG. 6 is a schematic cross-section of a light emitting device in accordance with Embodiment 6 of the present invention.

FIG. 7 is a schematic cross-section of a light emitting device in accordance with Embodiment 7 of the present invention.

FIG. 8 is a schematic cross-section of a light emitting device in accordance with Embodiment 8 of the present invention.

FIG. 9 is a schematic cross-section of a light emitting device in accordance with Embodiment 9 of the present invention.

FIG. 10 is a schematic cross-section of a light emitting device in accordance with Embodiment 10 of the present invention.

FIG. 11 is a schematic cross-section of a light emitting device in accordance with Embodiment 11 of the present invention.

FIG. 12 is a schematic cross-section of a conventional light emitting device.

### DESCRIPTION OF THE PREFERRED EMBODIMENTS

Specific embodiments of the present invention will be described in the following with reference to the figures. It is noted that when a silver alloy layer is formed on various portions such as an inner lead, the portion covered by the layer will be referred to as a “body”, in order to distinguish the silver alloy layer and the portion covered by the silver alloy layer. When the silver alloy layer is not formed, for example, when a silver layer is formed, the body and the surface layer of each portion will not be distinguished from each other. Therefore, in that case, the term “body” is not used, and if a layer other than the silver alloy layer is formed, description of the surface layer will not be given unless specified otherwise, and the surface layer will not be shown in the figure, either.

### Embodiment 1

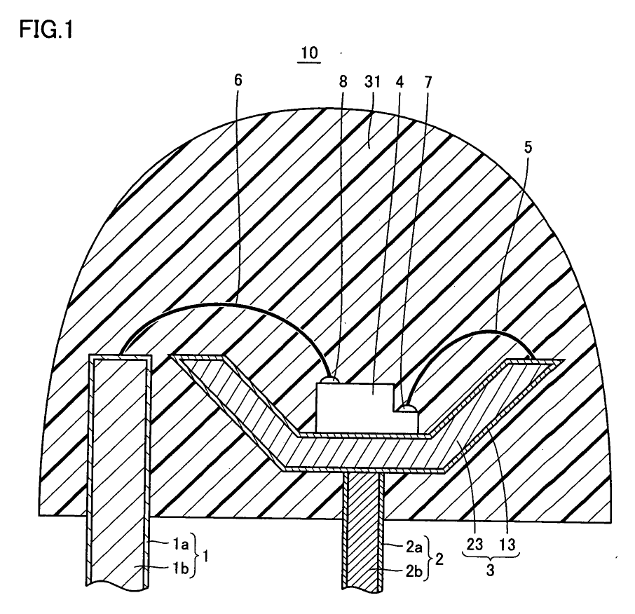

FIG. 1 is a schematic cross-sectional view of a light emitting device including copper lead frames 1, 2 and 3 having an Ag—Nd (0.7 at %) layer formed thereon, in accordance with Embodiment 1 of the present invention. Light emitting device 10 in accordance with the present embodiment includes a light emitting element 4, an inner lead 1 having a silver alloy layer 1a formed on an inner lead body 1b, a mount lead 2 having a silver alloy layer 2a formed on a mount lead body 2b, and a cup portion 3 surrounding light emitting element 4, having a silver alloy layer 13 formed on a cup portion body 23. At a bottom of cup portion 3, light emitting element 4 is mounted using Ag paste (not shown). Here, the silver alloy formed on the surface of these portions is Ag—Nd (0.7 at %), and its thickness is 100 nm. The Ag—Nd (0.7 at %) layer is formed by plating.

On light emitting element 4, n-type and p-type pad electrodes 7, 8 are formed, which are bonded with gold bonding wires 5 and 6, to attain electrical conduction to the outside. Then, a mold member 31 is formed in the shape of a convex lens, to cover cup portion 3 for mounting having silver alloy layer 13 formed thereon, light emitting element 4, inner lead 1 and mount lead 2. As the mold member, epoxy resin is used. Though it is not necessary, the mold member may contain phosphor as needed, for example, when white color is desired. Further, the phosphor may be arranged inside the cup portion and outside the mold member. Such a phosphor is not always necessary. As bonding wires 5 and 6, a gold wire, or a gold wire having a silver alloy layer formed on its surface may be used. The gold wire having a silver alloy layer formed on the surface is preferred. As the silver alloy layer for the gold wire, Ag—Nd (0.7 at %) may be used.

In light emitting device 10 described above, Ag—Nd (0.7 at %) layer is formed on the surfaces of copper lead frames 1, 2 and 3, and therefore, the surfaces of the lead frame are free from erosion. As a result, a light emitting device having high optical output and high reliability, from which light can efficiently be taken to the outside, can be realized.

### Embodiment 2

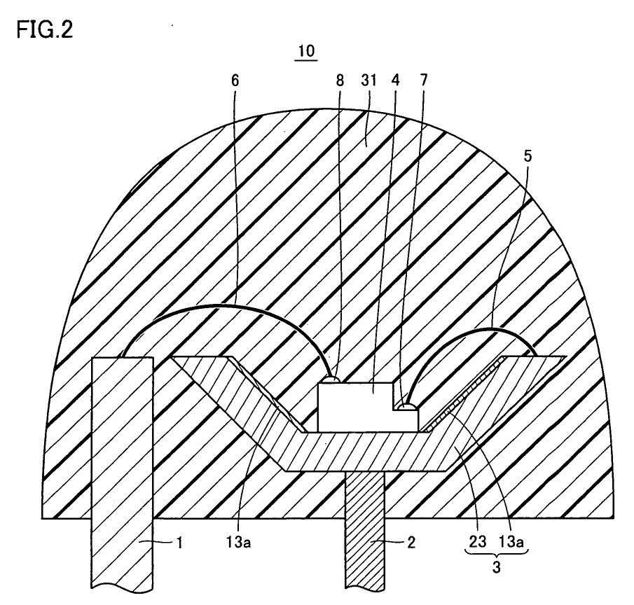

FIG. 2 is a schematic cross-sectional view of a light emitting device including silver-plated copper lead frames in accordance with Embodiment 2 of the present invention. Light emitting device 10 in accordance with the present embodiment includes light emitting element 4, inner lead 1, mount lead 2, and cup portion 3 for mounting light emitting element 4. At a bottom of mounting cup portion 3, light emitting element 4 is mounted using Ag paste (not shown). Here, on a side surface of cup portion 3, a silver alloy layer 13a is formed. Silver alloy layer 13a is of Ag—Nd (0.25 at %), and the thickness is 150 nm. The Ag—Nd (0.25 at %) is formed by plating.

On light emitting element 4, n-type and p-type pad electrodes 7, 8 are formed, which are bonded with gold bonding wires 5 and 6, to attain electrical conduction to the outside. Then, a mold member 31 is formed in the shape of a convex lens, to cover cup portion 3 for mounting light emitting element 4, light emitting element 4, inner lead 1 and mount lead 2. As the mold member, epoxy resin is used. As bonding wires 5 and 6, a gold wire, or a gold wire having a silver alloy layer formed on its surface may be used. The gold wire having a silver alloy layer formed on the surface is preferred.

In light emitting device 10 in accordance with the present embodiment, the light from light emitting element 4 is reflected with high reflectance from alloy layer 13a on the side surface of cup portion 3, whereby it becomes possible to take the light to the outside with high efficiency and to attain high optical output. Even when epoxy resin or the like as mold member 31 should be in contact with silver alloy layer 13a on the side surface of cup portion 3, erosion does not occur at the Ag—Nd (0.25 at %) layer as the reflection layer mentioned above, and therefore, reflectance does not decrease. Thus, it is possible to permanently take the light to the outside with high efficiency, and to attain high optical output.

### Embodiment 3

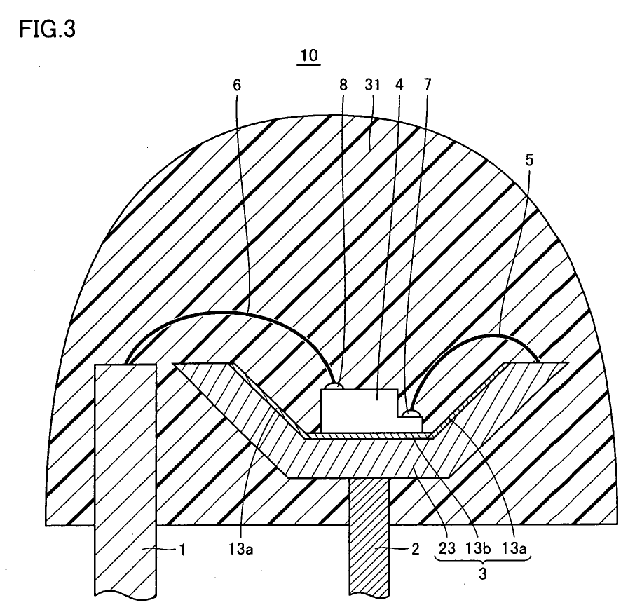

FIG. 3 is a schematic cross-sectional view of a light emitting device including silver-plated copper lead frames in accordance with Embodiment 3 of the present invention. Light emitting device 10 in accordance with the present embodiment includes light emitting element 4, inner lead 1, mount lead 2, and cup portion 3 for mounting light emitting element 4. Here, a silver alloy layer 13a is formed on a side surface of cup portion 3, and a silver alloy layer 13b is formed at the bottom of cup portion 3. As silver alloy layers 13a and 13b, Ag—Nd (1.0 at %) is used, and the thickness is 200 nm. At a bottom 32 of cup portion 3 for mounting, light emitting element 4 is mounted, using Ag paste. The Ag—Nd (1.0 at %) layer is formed by plating.

On the light emitting element, n-type and p-type pad electrodes 7, 8 are formed, which are bonded with gold bonding wires 5 and 6, to attain electrical conduction to the outside. Then, a mold member 31 is formed in the shape of a convex lens, to cover cup portion 3 for mounting light emitting element 4, light emitting element 4, inner lead 1 and mount lead 2. As the mold member, epoxy resin is used. As bonding wires 5 and 6, a gold wire, or a gold wire having a silver alloy layer formed on its surface may be used. The gold wire having a silver alloy layer formed on the surface is preferred.

In light emitting device 10 in accordance with the present embodiment, the light from light emitting element 4 is reflected with high reflectance from silver alloy layer 13a on the side surface and silver alloy layer 13b at the bottom surface of cup portion 3, whereby it is possible to take the light to the outside with high efficiency and to attain high optical output. Even when epoxy resin or the like as the mold member should be in contact not only with the side surface but also with the bottom surface of cup portion 3, erosion does not occur at the Ag—Nd (1.0 at %) layers 13a, 13b as the reflection layers, and therefore, reflectance does not decrease. Thus, the light can permanently be taken to the outside with high efficiency, and optical output higher than Embodiment 2 can be attained.

### Embodiment 4

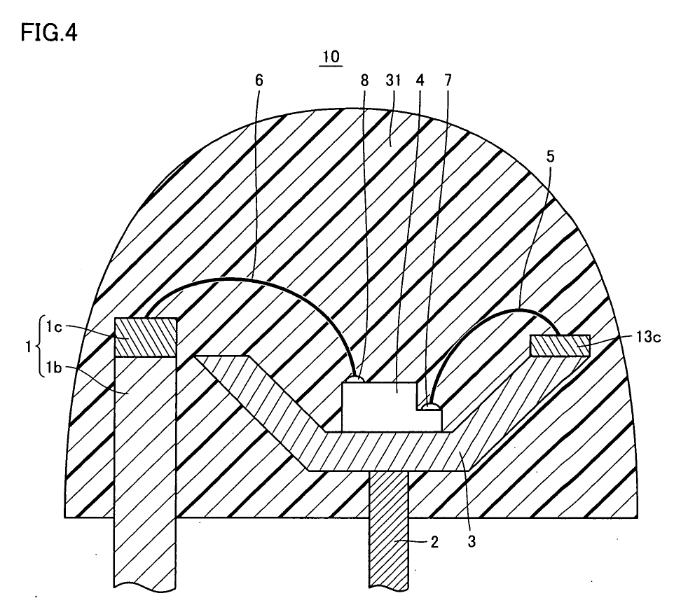

FIG. 4 is a schematic cross-sectional view of a light emitting device including a silver-plated copper lead frame in accordance with Embodiment 4 of the present invention. Light emitting device 10 in accordance with the present embodiment includes light emitting element 4, inner lead 1, mount lead 2, and cup portion 3 for mounting light emitting element 4. Here, silver alloy layers 1c and 13c are formed at portions of inner lead 1 and mount lead 2 where bonding wires 5 and 6 are connected. As silver alloy layers 1c and 13c, Ag—Nd (0.25 at %) is used, and the thickness is 100 nm. The Ag—Nd (0.25 at %) layer is formed by plating.

At the bottom of cup portion 3 for mounting, light emitting element 4 is mounted by using Ag paste (not shown). On light emitting element 4, n-type and p-type pad electrodes 7, 8 are formed, which are bonded with gold bonding wires 5 and 6, to attain electrical conduction to the outside. Then, a mold member 31 is formed in the shape of a convex lens, to cover cup portion 3 for mounting light emitting element 4, light emitting element 4, inner lead 1 and mount lead 2. As the mold member, epoxy resin is used. As bonding wires 5 and 6, a gold wire, or a gold wire having a silver alloy layer formed on its surface may be used. The gold wire having a silver alloy layer formed on the surface is preferred.

As Ag—Nd (0.25 at %) layers 1c and 13c are formed at the bonding portions of inner lead 1 and mount lead 2, the bonding portions are free from erosion, and successful bonding is possible. As a result, a light emitting device having permanently low driving voltage can be realized.

### Embodiment 5

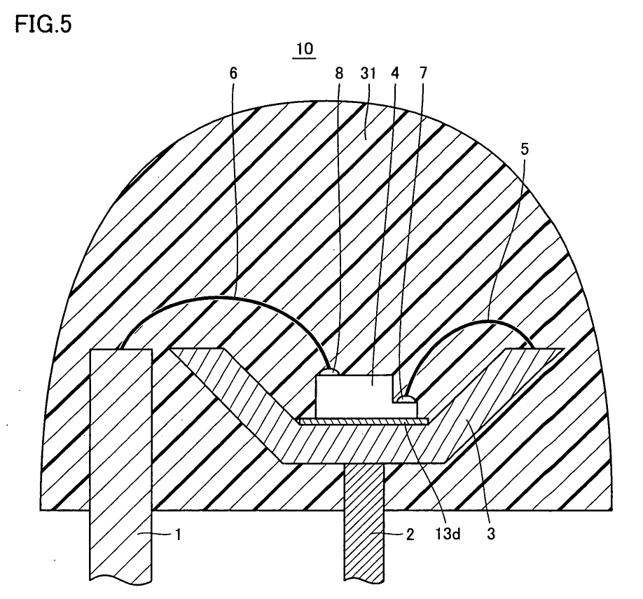

FIG. 5 is a schematic cross-sectional view of a light emitting device including a silver-plated copper lead frame in accordance with Embodiment 5 of the present invention. Light emitting device 10 in accordance with the present embodiment includes light emitting element 4, inner lead 1, mount lead 2, and cup portion 3 for mounting light emitting element 4. Here, a silver alloy layer 13d is provided at the bottom of cup portion 3. Here, on the surface of the bottom portion of cup portion 3, an Ag—Nd (0.7 at %)-Cu (0.9 at %) layer 13d is formed to the thickness of 100 nm. The Ag—Nd (0.7 at %)-Cu (0.9 at %) layer 13d is formed by plating.

On light emitting element 4, n-type and p-type pad electrodes 7, 8 are formed, which are bonded with gold bonding wires 5 and 6, to attain electrical conduction to the outside. On Ag—Nd (0.7 at %)-Cu (0.9 at %) layer 13d at the bottom of cup portion 3, light emitting element 4 is mounted using Ag paste (not shown). Then, a mold member 31 is formed in the shape of a convex lens, to cover cup portion 3 for mounting, light emitting element 4, inner lead 1 and mount lead 2. As the mold member, epoxy resin is used. As bonding wires 5 and 6, a gold wire, or a gold wire having a silver alloy layer formed on its surface may be used. The gold wire having a silver alloy layer formed on the surface is preferred.

As Ag—Nd (0.7 at %)-Cu (0.9 at %) layer 13d is formed at the bottom of cup portion 3, erosion resistance and surface smoothness of the mounting portion are improved, and hence, peeling or separation of the light emitting element can be prevented. Thus, a light emitting device having low driving voltage and high reliability can be realized.

### Embodiment 6

FIG. 6 is a schematic cross-sectional view of a light emitting device including silver-plated copper lead frames in accordance with Embodiment 6 of the present invention. Light emitting device 10 in accordance with the present embodiment includes light emitting element 4, inner lead 1, mount lead 2, and cup portion 3 for mounting light emitting element 4. Light emitting element 4 is mounted at the bottom of cup portion 3 using Ag paste having an Ag—Nd (0.7 at %) layer 15 on its surface. Here, the Ag—Nd (0.7 at %) layer 15 formed on the surface of Ag paste has the thickness of 100 nm. Ag—Nd (0.7 at %) layer 15 is formed by plating.

On light emitting element 4, n-type and p-type pad electrodes 7, 8 are formed, which are bonded with gold bonding wires 5 and 6, to attain electrical conduction to the outside. Then, a mold member 31 is formed in the shape of a convex lens, to cover cup portion 3 for mounting, having the silver alloy layer 15 formed thereon, light emitting element 4, inner lead 1 and mount lead 2. As the mold member, epoxy resin is used. As bonding wires 5 and 6, a gold wire, or a gold wire having a silver alloy layer formed on its surface may be used. The gold wire having a silver alloy layer formed on the surface is preferred.

Ag paste blackens after a long time when irradiated with light of ultra-violet to blue range. As the Ag—Nd (0.7 at %) layer is formed on the surface of the Ag paste, blackening can be avoided, and hence, a light emitting element free from peeling of the light emitting device, increase in operational voltage or lower reliability, can be realized.

### Embodiment 7

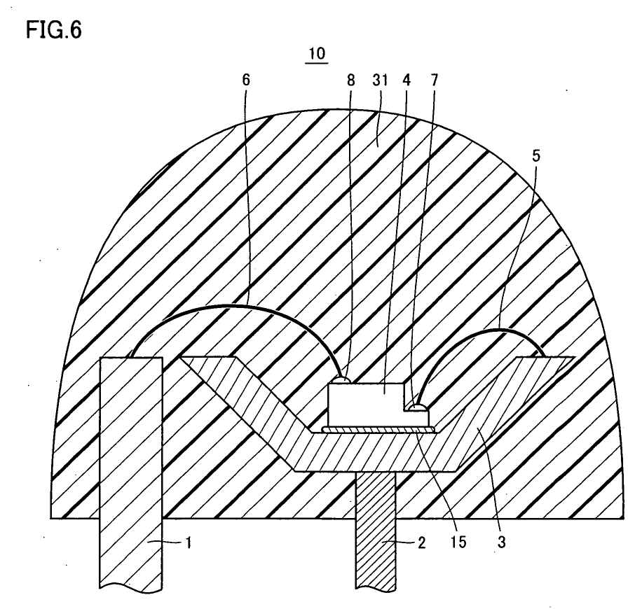

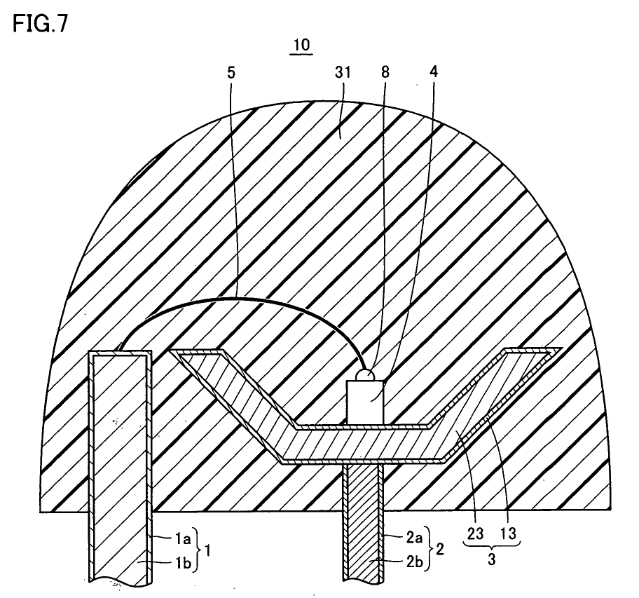

FIG. 7 is a schematic cross-sectional view of a light emitting device including a copper lead frame having an Ag—Nd (0.7 at %) layer formed on its surface, in accordance with Embodiment 7 of the present invention. Light emitting device 10 in accordance with the present embodiment includes a light emitting element 4, and inner lead 1, mount lead 2 and cup portion 3 for mounting the light emitting element, having a silver alloy layer formed thereon. At the bottom of cup portion 3 for mounting, light emitting element 4 is mounted using Ag paste. Here, the Ag—Nd (0.7 at %) layers 1a, 2a and 13 formed on the surface have the thickness of 100 nm. The Ag—Nd (0.7 at %) layers are formed by plating.

On light emitting element 4, an n-type pad electrode 8 is formed, which is bonded with gold bonding wire 5, to attain electrical conduction to the outside. Mold member 31 is formed in the shape of a convex lens, to cover cup portion 3 for mounting, having the silver alloy layer formed thereon, light emitting element 4, inner lead 1 and mount lead 2. As the mold member, epoxy resin is used. As bonding wire 5, a gold wire, or a gold wire having a silver alloy layer formed on its surface may be used. The gold wire having a silver alloy layer formed on the surface is preferred.

As the Ag—Nd (0.7 at %) layers 1a, 2a and 13 are formed on the surface of the copper lead frame, erosion or the like do not occur at the surface of the lead frame. As a result, a light emitting device having high optical output and high reliability, from which light can efficiently be taken to the outside permanently, can be realized.

### Embodiment 8

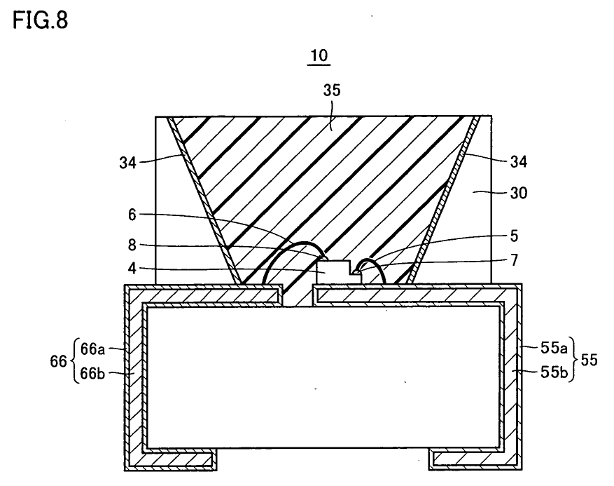

FIG. 8 is a schematic cross-sectional view of a light emitting device including a surface-mounting type frame, in which an Ag—Bi (0.14 at %) layer is formed on package electrodes and on a side surface of the frame, in accordance with Embodiment 8 of the present invention. Light emitting device 10 in accordance with the present embodiment includes a positive package electrode 66 having a silver alloy layer 66a formed on a surface of body 66b, a negative package electrode 55 having a silver alloy layer 55a formed on a surface of body 55b, and a cup portion 30 for mounting light emitting element 4. On a side surface of the frame, a silver alloy layer 34 is formed. At the bottom of cup portion 30, light emitting element 4 is mounted on negative package electrode 55, using Ag paste (not shown). Here, the thickness of Ag—Bi (0.14 at %) layer 34 is 100 nm. Ag—Bi (0.14 at %) layer 34 is formed by plating.

On the light emitting element 4, n-type and p-type pad electrodes 7, 8 are formed, which are bonded with gold bonding wires 5 and 6, to attain electrical conduction to the outside. Then, a mold member 35 is formed to cover cup portion 30 for mounting having the silver alloy layer and light emitting element 4. As the mold member, epoxy resin is used. As bonding wires 5 and 6, a gold wire, or a gold wire having a silver alloy layer formed on its surface may be used. The gold wire having a silver alloy layer formed on the surface is preferred.

As Ag—Bi (0.14 at %) layers 66a, 55a and 34 are formed on the surfaces of copper electrodes and cup portion, the surfaces of these portions are free from erosion. As a result, a light emitting device having high optical output and high reliability, from which light can efficiently be taken to the outside permanently, can be realized.

### Embodiment 9

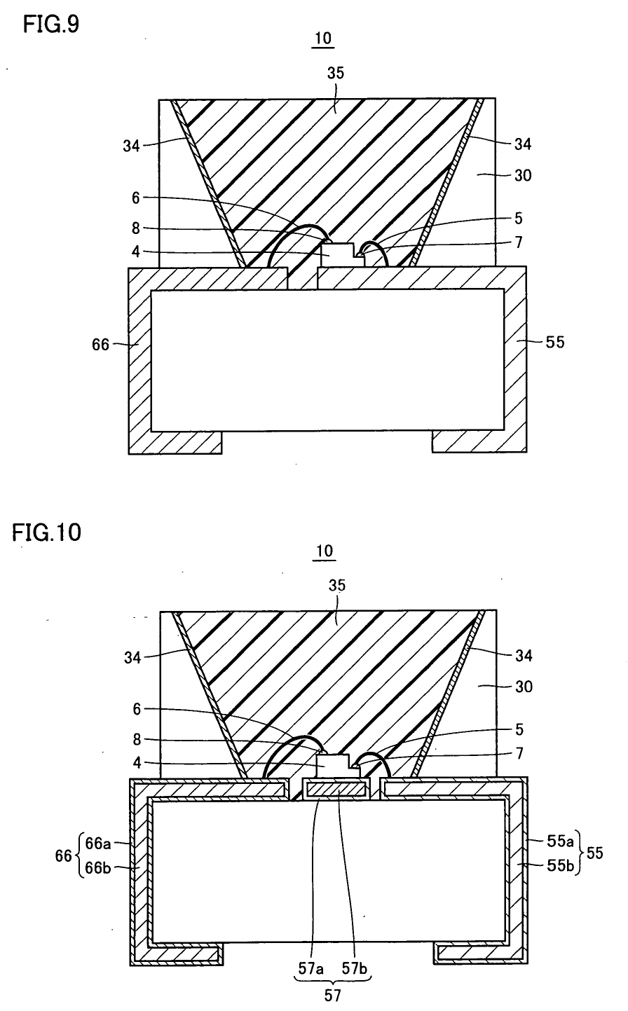

FIG. 9 is a schematic cross-sectional view of a light emitting device including a surface-mounting type frame, in which an Ag—Nd (0.7 at %) layer is formed on a side surface of the frame, in accordance with Embodiment 9 of the present invention. Light emitting device 10 in accordance with the present embodiment includes an Ag—Nd (0.7 at %) layer 34 formed on a side surface of the frame, a positive package electrode 66, a negative package electrode 55 on which light emitting element 4 is mounted, and a cup portion 30. Light emitting element 4 is mounted on negative package electrode 55 by using Ag paste. Here, Ag—Nd (0.7 at %) layer 34 formed on the surface has the thickness of 100 nm. Ag—Nd (0.7 at %) layer 34 is formed by plating.

On the light emitting element 4, n-type and p-type pad electrodes 7, 8 are formed, which are bonded with gold bonding wires 5 and 6, to attain electrical conduction to the outside. Then, a mold member 35 is formed to cover cup portion 30 for mounting having the silver alloy layer 34 formed thereon and light emitting element 4. As the mold member, epoxy resin is used. As bonding wires 5 and 6, a gold wire, or a gold wire having a silver alloy layer formed on its surface may be used. The gold wire having a silver alloy layer formed on the surface is preferred.

In light emitting device 10 in accordance with the present embodiment, light is reflected with high reflectance at the side surface of the cup portion having Ag—Nd (0.7 at %) layer 34 formed thereon, so that light can be taken to the outside with high efficiency, and high optical output can be attained. Even when epoxy resin or the like as mold member 35 should be in contact with the side surface of cup portion 30, erosion does not occur at the Ag—Nd (0.7 at %) layer 34 as the reflection layer mentioned above, and therefore, reflectance does not decrease. Thus, the light can permanently be taken to the outside with high efficiency, and high optical output can be attained.

### Embodiment 10

FIG. 10 is a schematic cross-sectional view of a light emitting device including a surface-mounting type frame, in which an Ag—Nd (0.25 at %) layer is formed on a mounting surface and on the surfaces of positive and negative package electrodes in accordance with Embodiment 10 of the present invention. Light emitting device 10 in accordance with the present embodiment includes a mounting surface 57 and positive and negative package electrodes 66 and 55, and on the surfaces of respective bodies 57b, 66b and 55b, silver alloy layers 57a, 66a and 55a are formed. Silver alloy layers 57a, 66a and 55a are of Ag—Nd (0.25 at %). Light emitting element 4 is mounted on mounting surface 57 using Ag paste. Here, Ag—Nd (0.25 at %) layers 57a, 66a and 55a have the thickness of 100 nm. Ag—Nd (0.25 at %) layers 57a, 66a and 55a are formed by plating.

On the light emitting element 4, n-type and p-type pad electrodes 7, 8 are formed, which are bonded with gold bonding wires 5 and 6, to attain electrical conduction to the outside. Then, a mold member 35 is formed to cover mounting surface 57 and positive and negative package electrodes 66, 55 on which the silver alloy layer is formed and light emitting element 4. As the mold member, epoxy resin is used. As bonding wires 5 and 6, a gold wire, or a gold wire having a silver alloy layer formed on its surface may be used. The gold wire having a silver alloy layer formed on the surface is preferred.

As the Ag—Nd (0.25 at %) layers 57a, 66a and 55a are formed, corrosion resistance and surface smoothness of the mounting portion are improved, so that peeling or separation of the light emitting element can be prevented. Thus, a light emitting device having low driving voltage and high reliability can be realized.

### Embodiment 11

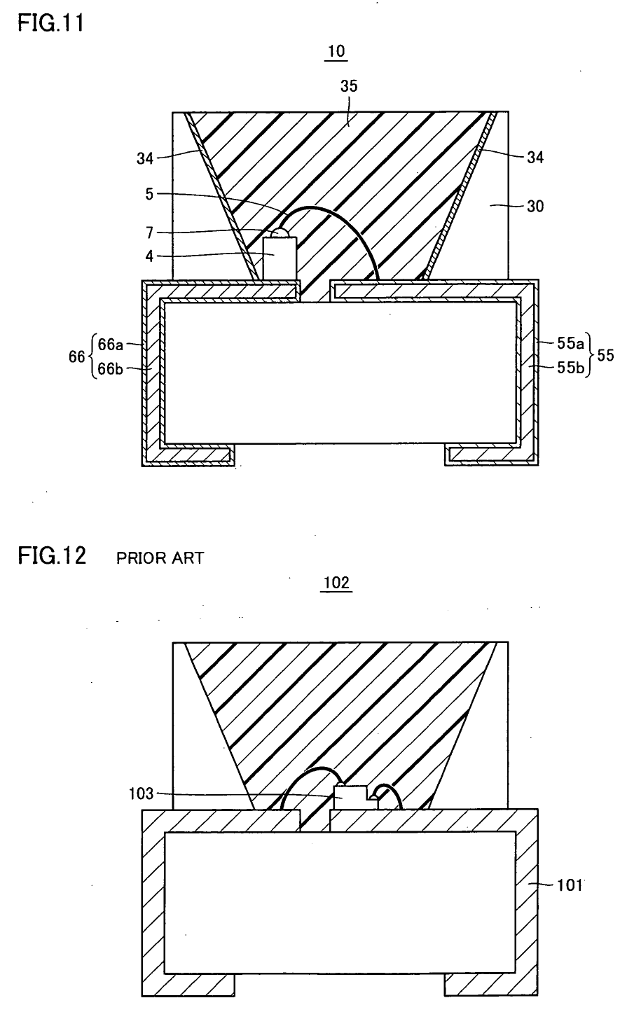

FIG. 11 is a schematic cross-sectional view of a light emitting device including a surface-mounting type frame, in which an Ag—Nd (0.7 at %)-Cu (0.9 at %) layer is formed on the surfaces of positive and negative package electrodes, in accordance with Embodiment 11 of the present invention. Light emitting device 10 in accordance with the present embodiment includes positive and negative package electrodes 66 and 55, and on the surface of respective bodies 66b and 55b, Ag—Nd (0.7 at %)-Cu (0.9 at %) layers 66a and 55a are formed. Light emitting element 4 is mounted on negative package electrode 55 on which Ag—Nd (0.7 at %)-Cu (0.9 at %) layer 55a is formed, using Ag paste (not shown). Here, Ag—Nd (0.7 at %)-Cu (0.9 at %) layers 66a and 55a formed on respective bodies 66b and 55b have the thickness of 100 nm. Ag—Nd (0.7 at %)-Cu (0.9 at %) layers 66a and 55a are formed by plating.

On light emitting element 4, an n-type pad electrode 7 is formed, which is bonded with gold bonding wire 5, to attain electrical conduction to the outside. Then, a mold member 35 is formed to cover mounting surface 57 and positive and negative package electrodes 66, 55 on which the silver alloy layer is formed and light emitting element 4. As the mold member, epoxy resin is used. As bonding wires 5 and 6, a gold wire, or a gold wire having a silver alloy layer formed on its surface may be used. The gold wire having a silver alloy layer formed on the surface is preferred.

In light emitting device 10 in accordance with the present embodiment, as —Nd (0.7 at %)-Cu (0.9 at %) layers 66a and 55a are formed, corrosion resistance and surface smoothness of the mounting portion are improved, so that peeling or separation of the light emitting element can be prevented. Thus, a light emitting device having low driving voltage and high reliability can be realized.

In the embodiments of the present invention, the silver alloy layer may include Ag—Nd, Ag—Nd—Cu, Ag—Pd, Ag—Pd—Cu, Ag—Bi, and Ag—Nd—Au. These silver alloy layers realize high reflectance, high thermal conductivity, high resistance to halogen, improved corrosion resistance, improved heat resistance, improved aggregation resistance and improved stability of surface smoothness. Ag alloys of Ag—Nd and Ag—Bi are particularly preferable, as Ag—Nd improves reflectance, thermal conductivity, heat resistance, aggregation resistance and stability of surface smoothness, while Ag—Bi improves reflectance, thermal conductivity, halogen resistance and corrosion resistance.

As specific material of the mold member of the embodiments of the present invention, mainly, glass or transparent resin having superior weather resistance, such as epoxy resin, urea resin or silicone resin may suitably be used. As the material of surface-mounting type package, resin such as polycarbonate, polyphenylene sulfide (PPS), liquid crystal polymer (LCP), ABS resin, epoxy resin, phenol resin, acryl resin or PBT resin may be used.

As the light emitting element used in the embodiments of the invention, one prepared by forming a semiconductor such as GaAlN, ZnS, ZnSe, SiC, GaP, GaAlAs, AlInGaP, InGaN, GaN, AlInGaN or the like as a light emitting layer on a substrate by liquid phase deposition of MOCVD method is used. As the semiconductor structure, a double-hetero structure having a pn junction may be used. In accordance with the material or ratio of mixed crystal of the semiconductor layer, various emission wavelengths from ultra-violet to infra-red can be selected. Further, the light emitting layer may be adapted to have a single quantum well structure or multi-quantum well structure.

As a semiconductor material of high luminance, gallium nitride based compound semiconductor is preferably used for green and blue. For red, use of gallium/aluminum/arsenic based semiconductor or aluminum/indium/gallium/phosphorus based semiconductor light emitting element is preferred. Various materials may be used for the light emitting element in accordance with intended use. For full-color emission, the semiconductor light emitting elements for R (Red), G (Green) and B (Blue), should preferably has the emission wavelength of 600 nm to 700 nm for R: red, 495 nm to 565 nm for G: green and 430 nm to 4990 nm for B: blue.

It is needless to say that a phosphor may be included in the embodiments of the present invention. By way of example, the phosphor may be based on an yttrium/aluminum oxide based phosphor activated with cerium, that emits light when excited by light emitted from a semiconductor light emitting element having a nitride based compound semiconductor as a light emitting layer. Specific yttrium/aluminum oxide based phosphor may include YAlO₃:Ce, Y₃Al₅O₁₂:Ce, Y₄Al₂O₉:Ce and mixture thereof. As already described, embodiments described above may include embodiments with such phosphor.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A light emitting element mounting frame, having a silver alloy layer formed on at least a portion of its surface.

2. The light emitting element mounting frame according to claim 1, wherein
said Ag alloy is any of Ag—Nd alloy, Ag—Nd—Cu alloy, Ag—Pd alloy, Ag—Pd—Cu alloy, Ag—Bi alloy and Ag—Nd—Au alloy.

3. The light emitting element mounting frame according to claim 1, wherein said Ag alloy layer is formed by any of vapor deposition, resistance heating and plating.

4. The light emitting element mounting frame according to claim 1, wherein
said frame is a lead frame including a cup portion positioned to surround said light emitting element, and the Ag alloy layer is formed on at least a portion of the lead frame.

5. The light emitting element mounting frame according to claim 4, wherein
said Ag alloy layer is formed on an inner side of said cup portion facing the light emitting element.

6. The light emitting element mounting frame according to claim 4, wherein
said Ag alloy layer is formed on a side surface of said cup portion.

7. The light emitting element mounting frame according to claim 4, wherein
said Ag alloy layer is formed on a bottom of said cup portion.

8. The light emitting element mounting frame according to claim 4, wherein
said Ag alloy layer is formed on a portion where said lead frame contacts resin.

9. The light emitting element mounting frame according to claim 4, wherein
said Ag alloy layer is formed on a region to be wire-bonded of said lead frame.

10. The light emitting element mounting frame according to claim 1, wherein
said frame is a surface-mounting type frame including a portion where said light emitting element is mounted, an electrode terminal and a cup portion positioned to surround said light emitting element, and an Ag alloy layer is formed at any of the portion where said light emitting element is mounted, the electrode terminal and the cup portion positioned to surround said light emitting element.

11. The light emitting element mounting frame according to claim 10, wherein
said Ag alloy layer is formed on an inner side of said cup portion facing the light emitting element.

12. The light emitting element mounting frame according to claim 10, wherein
said Ag alloy layer is formed on a portion in contact with resin of said cup portion.

13. The light emitting element mounting frame according to claim 10, wherein
said Ag alloy layer is formed on a portion in contact with a phosphor of said cup portion.

14. The light emitting element mounting frame according to claim 10, wherein
said Ag alloy layer is formed on a region to be wire-bonded to said electrode terminal.

15. A light emitting device, using a frame having a silver alloy layer formed on at least a portion of its surface, for mounting a light emitting element, wherein
a conductive adhesive used for fixing said light emitting element to said frame contains Ag as a main component and additionally contains at least Nd.

16. The light emitting device according to claim 15, wherein
said light emitting element is a light emitting diode of infra-red to ultra-violet.

17. The light emitting device according to claim 15, wherein
said light emitting element is any of three chips of red, green and blue LEDs, one chip 6f blue LED, and one chip of ultra-violet LED.

18. A light emitting device, using a frame having a silver alloy layer formed on at least a portion of its surface, for mounting a light emitting element, wherein
a conductive adhesive used for fixing said light emitting element is Ag paste having an Ag alloy layer formed on paste surface.

19. The light emitting device according to claim 18, wherein said light emitting element is a light emitting diode of infra-red to ultra-violet.

20. The light emitting device according to claim 18, wherein
said light emitting element is any of three chips of red, green and blue LEDs, one chip of blue LED, and one chip of ultra-violet LED.

21. A light emitting device, using a frame having a silver alloy layer formed on at least a portion of its surface, for mounting a light emitting element, wherein
said light emitting element includes at least one wire per one surface.

22. The light emitting device according to claim 21, wherein said light emitting element is a light emitting diode of infra-red to ultra-violet.

23. The light emitting device according to claim 21, wherein
said light emitting element is any of three chips of red, green and blue LEDs, one chip of blue LED, and one chip of ultra-violet LED.
